(19) United States
(12) Patent Application Publication
(10) Pub. No.: US 2023/0111831 A1
(43) Pub. Date: Apr. 13, 2023

(54) MODULAR SUSTAINABLE POWER PLANT FOR HARVESTING NON-VOLCANIC GEOTHERMAL HEAT

(71) Applicant: Ruslan Asfandiyarov, Lausanne (CH)

(72) Inventor: Ruslan Asfandiyarov, Lausanne (CH)

(21) Appl. No.: 17/937,984

(22) Filed: Oct. 4, 2022

Related U.S. Application Data
(60) Provisional application No. 63/252,243, filed on Oct. 5, 2021.

(30) Foreign Application Priority Data
Oct. 4, 2022 (WO) PCT/IB2022/059477

(51) Int. Cl. F03G 7/04; F24T 10/30; F24V 50/00

(52) U.S. Cl. CPC F03G 7/047; F24T 10/30; F24V 50/00

(57) ABSTRACT

A modular power plant system may include a plurality of thermal energy conversion elements installed in multiple cavities in the bottom of the well or along the well. The thermal energy conversion elements may convert geothermal heat directly to electricity. A surface infrastructure may consist of electricity distribution racks and pumps that drive cooling liquid in closed or open loops to cool the thermal energy conversion elements. AC or DC voltage may be communicated from each of the thermal energy conversion elements to the surface infrastructure for the distribution of electricity in a decentralized power grid.

### CROSS-REFERENCE TO RELATED APPLICATIONS

This application claims the benefit of U.S. Provisional Pat. Application No. 63/252,243 filed Oct. 5, 2021.

### TECHNICAL FIELD

The embodiments disclosed herein generally relate to systems and methods for harvesting non-volcanic geothermal heat.

### BACKGROUND

It is estimated that over seventy percent of greenhouse gases can be traced back to energy production. The increased use of renewable energy sources is the key to a more sustainable future. However, today’s green energy sources are not sufficient to entirely phase out fossil fuels within the foreseeable future. Wind, solar, and hydro energy all have limitations, due to their significant land use, disturbance of existing ecosystems, and inability to provide baseload power. Most importantly, use of these technologies is often tied to specific regions and not readily universally available. Hybrid systems are expensive and still cannot provide power at industrial scale.

Non-volcanic geothermal heat in the Earth’s crust is, in essence, a slow-burning natural nuclear reactor with no radioactive waste. The energy capacity of this resource surpasses all current and future needs of humanity for thousands of years.

Almost everywhere on earth, apart from areas with active volcanoes where high temperatures are present thanks to magma reaching the surface, the temperature increases with depth by an average of 25° C. per kilometer. This temperature change can be turned into energy but is not dense enough for any existing solution to be viable. Conventional geothermal plants can only be operated with volcanic primordial heat. Newer technologies still rely on conventional approaches to gather heat and convert it to electricity. None of the solutions currently available on the market are simultaneously scalable and environmentally friendly.

### SUMMARY

This summary is provided to introduce a variety of concepts in a simplified form that is further disclosed in the detailed description of the embodiments. This summary is not intended to identify key or essential inventive concepts of the claimed subject matter, nor is it intended for determining the scope of the claimed subject matter.

The disclosed system generally relates to a modular, scalable sustainable electricity production plant for harvesting non-volcanic geothermal heat, on an industrial scale anywhere in the world, regardless of local geological features. At the same time, nothing limits its application for harvesting volcanic geothermal heat. The system may be sustainable, with zero-carbon footprint, no atmospheric emissions, and without burning any fossil fuel.

In general, the system may include drilling a deep well of a few hundred meters to a few kilometers depending on energy needs and the geological structure. Thermal energy conversion elements are installed in multiple cavities on the bottom of the well. They convert the geothermal heat directly to electricity. A surface infrastructure consists of electricity distribution racks, and pumps that drive cooling liquid in closed or open loops. The surface infrastructure can be placed underground at shallow depths keeping it completely out of sight.

In one aspect, the system may include a modular electricity generation power plant constructed and arranged to harvest non-volcanic geothermal heat based on thermoelectric technology and close loop cooling system.

In one aspect, the system may gather energy via thermal conductivity by implementing thermoelectric generators (TEGs) that convert temperatures difference directly into electrical energy.

In one aspect, the system may allow for the decentralization of power grids by implementing a modular geothermal power plant.

Other illustrative variations within the scope of the invention will become apparent from the detailed description provided hereinafter. The detailed description and enumerated variations, while disclosing optional variations, are intended for purposes of illustration only and are not intended to limit the scope of the invention.

### BRIEF DESCRIPTION OF THE DRAWINGS

A complete understanding of the present embodiments and features thereof will be more readily understood by reference to the following detailed description when considered in conjunction with the accompanying drawings, wherein:

FIG. 1 illustrates a simplified system diagram of one variation of a modular sustainable power plant for harvesting non-volcanic geothermal heat according to some embodiments described herein;

FIG. 2A illustrates a simplified system diagram of one variation of a modular sustainable power plant for harvesting non-volcanic geothermal heat according to some embodiments described herein;

FIG. 2B illustrates a simplified system diagram of one variation of a modular sustainable power plant for harvesting non-volcanic geothermal heat according to some embodiments described herein;

FIG. 2C illustrates a simplified system diagram of one variation of a modular sustainable power plant for harvesting non-volcanic geothermal heat according to some embodiments described herein;

FIG. 3 illustrates a simplified system diagram of one variation of a modular sustainable power plant for harvesting non-volcanic geothermal heat according to some embodiments described herein; and

FIG. 4 illustrates a simplified system diagram of one variation of a modular sustainable power plant for harvesting non-volcanic geothermal heat according to some embodiments described herein.

The drawings are not necessarily to scale, and certain features and certain views of the drawings may be shown exaggerated in scale or in schematic in the interest of clarity and conciseness and should not be considered limiting.

### DETAILED DESCRIPTION

The specific details of the single embodiment or variety of embodiments described herein are to the described system and methods of use. Any specific details of the embodiments are used for demonstration purposes only and no unnecessary limitations or inferences are to be understood from there.

It is noted that the embodiments reside primarily in combinations of components and procedures related to the system. Accordingly, the system components have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

In general, the system may provide for a method of conversion of geothermal heat to electricity occurring in thermal energy conversion modules installed in the bottom of a well or along the length of a well and connected in series to create desired voltage output and in parallel for required power. Each module may include thermoelectric elements such as TEGs with a hot-side facing outwards towards a well-wall or borehole wall and a cold-side exposed to cooling lines or a cooling system. The cooling lines may encapsulate DC electronics and DC/AC converters used to transfer electricity to the surface. The temperature of the coolant is maintained at shallow depth temperatures via ambient cooling or additional cooling systems.

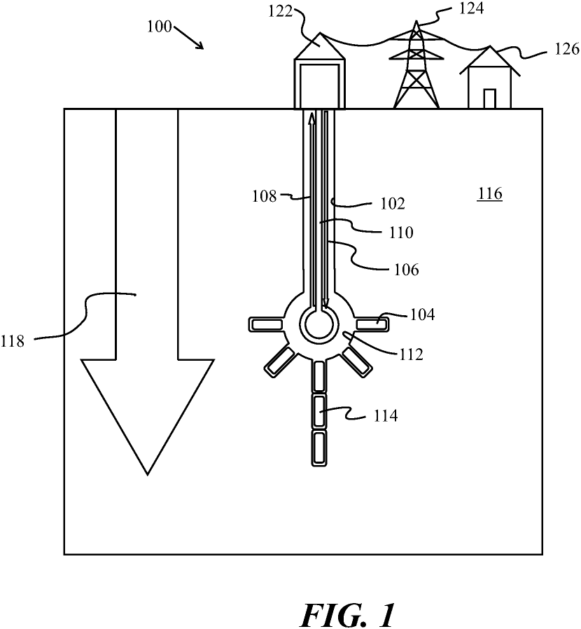

Referring to FIG. 1, a modular power plant system 100 may include a well shaft 102 defined within a portion of the earth’s crust 116 which has been dug or drilled prior to installation of the modular power plant system 100. The well shaft 102 may include a well bottom 112. The earth’s crust 116 may include a temperature gradient 118 that, in general, may increase in temperature with the depth of the well shaft 102 and well bottom 112. Thermal energy conversion modules 104 may be disposed in parallel within boreholes or in series within boreholes. The plurality of modules 104 may be in operable communication with surface infrastructure 122 which may be in operable communication with an electricity distribution system 124 and end user electrical needs 126. According to some embodiments, electricity distribution system 124 may be disposed wholly or partially underground and in operable communication directly with end user needs 126. Each of the modules within the plurality of modules 104 may convert geothermal heat to DC or AC voltage and communicate voltage to surface infrastructure 122 via power transmission lines 110. The modular power plant system may include a closed or open loop cooling system in operable communication with each of the modules 104 including a coolant delivery system 106 and coolant receiving system 108. The closed or open loop cooling system may be in operable communication with the surface infrastructure and may be constructed and arranged to flow cooling fluid through the system and draw heat away from the plurality of modules 104 and dissipate said heat via ambient cooling near surface level portions of the well shaft 102 or via additional cool cooling systems within the well shaft 102, or surface infrastructure 122.

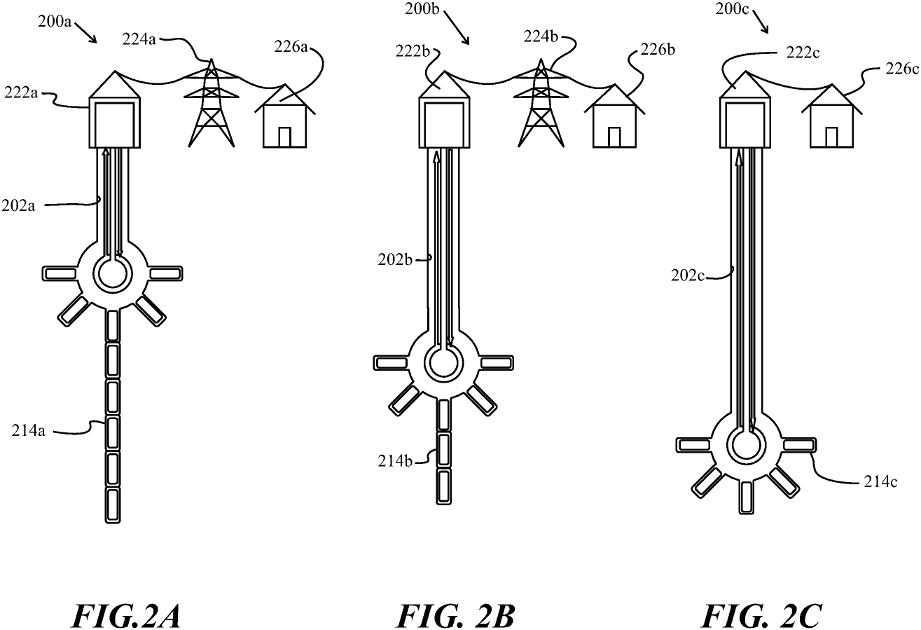

Referring to FIG. 2A a modular power plant system 200a may include a similar implementation as described with respect to FIG. 1 including a plurality of modules 214a disposed in series within a well shaft 202a that may be in operable communication with surface infrastructure 222a in operable communication with an electric city distribution system 224a and end user electrical needs 226a. Variations on the systems depicted in FIG. 1 and FIG. 2A are also shown in FIGS. 2B and 2C including systems 200a, 200b, and 200c having varying depths of well shaft 202b and 202c as well as varying arrangements of modules 214b and 214b including various arrangements of modules in series, parallel, or combinations of the two. According to some variations, as best seen in FIG. 2C, a modular power plant system 200c may include a surface infrastructure 222c that may be in operable communication with end user electrical needs 226c. Many other variations on the system, well shaft infrastructure, well bottom arrangements, and modules in parallel, series, or both are contemplated by this disclosure and any arrangements shown in the figures should not be considered limiting. As a non-limiting example, it is contemplated that the system may incorporate various diverging well shafts in a branch or root like arrangement and not necessarily as a vertical shaft as depicted in the simplified variations depicted in the figures.

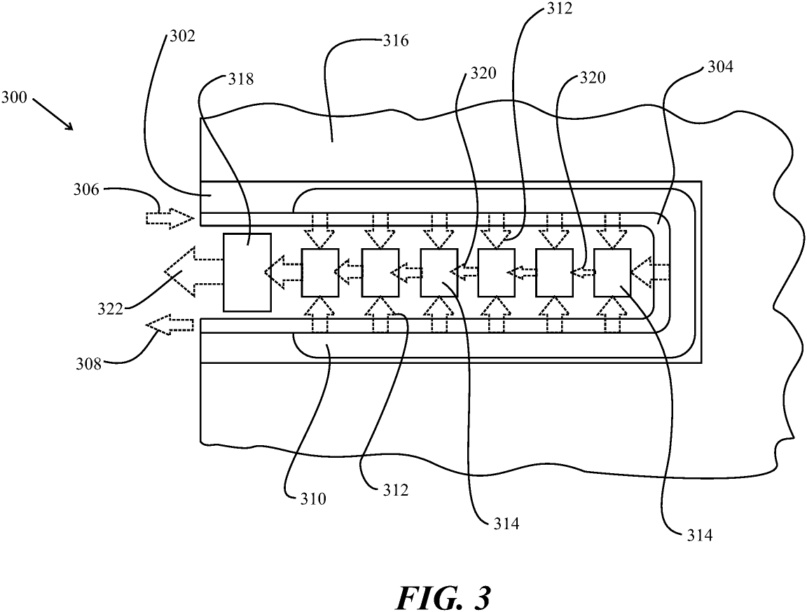

Referring to FIG. 3, a thermal energy conversion element 300 may be constructed and arranged for the conversions of temperatures difference directly into electrical energy via devices such as TEGs. According to one embodiment, a thermal energy conversion element 300 may be disposed within a portion of the earth’s crust 316 and may be constructed and arranged to convert temperature differences into electrical energy. The module 300 may be disposed within a borehole 302 and may include a thermoelectric generator 310 being disposed approximately against the wall of the borehole 302 and in operable communication the coolant system 304 including a coolant delivery system 306 and coolant receiving system 308 which may be in operable communication with surface infrastructure. The thermoelectric converter 310 may be constructed and arranged to convert temperature difference to electrical energy 312 which may be received by at least one DC collector 314 disposed within the module 300. According to some embodiments, of plurality of DC collectors 314 may be arranged in series and may operably communicate DC voltage 320 to at least one DC to AC converter 318. Alternatively, DC to AC converter 318 may also be another DC collector making the whole system function in DC mode. AC or DC voltage 322 may be communicated to surface infrastructure thereby providing power to end users and creating an optionally decentralization of power grids.

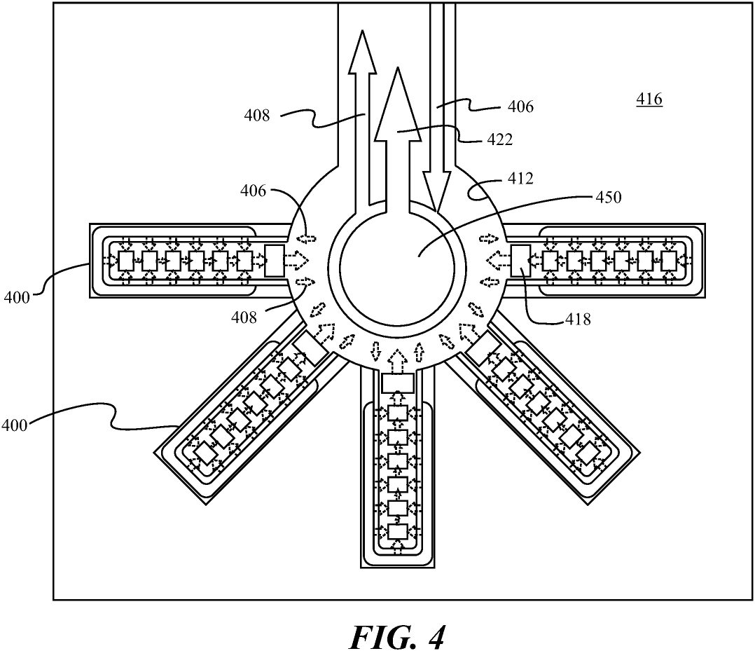

Referring to FIG. 4, a modular power plant system may include a plurality of thermal energy conversion elements 400 disposed within boreholes within a bell bottom 412 defined by the earth’s crust 416. Each of the modules 400 may be in operable communication with AC to DC converter (or DC collector) 418 and a closed or open loop cooling system. According to some embodiments, each of the modules 400 may include a TEG or plurality of TEGs with a hot-side facing the borehole wall or well-shaft wall and a cold-side exposed to the cooling system. According to some embodiments, the modules 400 may be in operable communication with an electrical system 450 constructed and arranged to communicate AC or DC voltage 422 to surface infrastructure. According to some embodiments, the electrical system 450 may be constructed and arranged for AC or DC power collection, regulation, transformation, and transmission to ensure efficient power transfer to the surface. According to some embodiments, modules 400 may share the described cooling system or may utilize individual cooling systems.

The following description of variants is only illustrative of components, elements, acts, products, and methods considered to be within the scope of the invention and are not in any way intended to limit such scope by what is specifically disclosed or not expressly set forth. The components, elements, acts, products, and methods as described herein may be combined and rearranged other than as expressly described herein and are still considered to be within the scope of the invention.

According to variation 1, a modular power plant system may include an electricity distribution system; a surface infrastructure in operable communication with the electricity distribution system; at least one thermal energy conversion module disposed within a borehole within the earth crust and being in operable communication with the surface infrastructure, wherein the at least one thermal conversion module is constructed and arranged to convert geothermal heat to DC or AC voltage and communicate voltage to the surface infrastructure; and at least one of a closed or open loop cooling system constructed and arranged to draw heat away from the at least one thermal energy conversion module and dissipate said heat via at least one of ambient cooling near surface level portions of the borehole or on the surface via a dedicated cooling system.

Variation 2 may include a modular power plant system as in variation 1, wherein the at least one thermal energy conversion module is a plurality of thermal energy conversion modules.

Variation 3 may include a modular power plant system as in variations 1 or 2, wherein the plurality of thermal energy conversion modules are disposed in in parallel within the borehole.

Variation 4 may include a modular power plant system as in any of variations 1 through 3, wherein the plurality of thermal energy conversion modules are disposed in series within the borehole.

Variation 5 may include a modular power plant system as in any of variations 1 through 4, wherein the plurality of thermal energy conversion modules are disposed partially in parallel and partially in series within the borehole.

Variation 6 may include a modular power plant system as in any of variations 1 through 5, and may further include at least one additional cooling system constructed and arranged to draw heat away from the at least one thermal energy conversion module.

Variation 7 may include a modular power plant system as in any of variations 1 through 6, wherein the borehole is part of a at least one of a pre-existing well, drilled hole, or structure with constant heat flow.

Variation 8 may include a modular power plant system as in any of variations 1 through 7, wherein the at least one thermal energy conversion module includes a thermoelectric generator may include a hot side opposite a cool side.

Variation 9 may include a modular power plant system as in any of variations 1 through 8, wherein the at least one of a closed or open loop cooling system is constructed and arranged to draw heat from the cool side of the thermoelectric generator and dissipate heat via at least one of ambient cooling near surface level portions of the borehole or a dedicated cooling system.

Variation 10 may include a modular power plant system as in any of variations 1 through 9, wherein the at least one thermal energy conversion module further includes at least one DC collector in operable communication with at least DC to AC converter.

Variation 11 may include a modular power plant system as in any of variations 1 through 10, wherein the at least one of a closed or open loop cooling system includes a coolant delivery system and a coolant receiving system in operable communication with surface infrastructure.

According to variation 12, a thermal energy conversion module may include a thermoelectric generator may include an outer surface and an inner surface and defining a cavity therein, the thermal electric generator being constructed and arranged to convert temperature difference between the outer surface and the inner surface into electrical energy; at least one of a closed or open loop cooling system disposed approximately withing the cavity of the thermal electric converter; at least one DC collector constructed and arranged to collect electrical energy from the thermoelectric generator; and at least one DC to AC converter constructed and arranged to receive DC voltage from the DC collector.

Variation 13 may include thermal energy conversion module as in variation 12 wherein the at least one of a closed or open loop cooling system at least partially encapsulates the at least one DC collector and the at least one DC to AC converter.

Variation 14 may include thermal energy conversion module as in variations 12 or 13, wherein the at least one of a closed or open loop cooling system includes a coolant delivery system and a coolant receiving system in operable communication with surface infrastructure.

Variation 15 may include thermal energy conversion module as in any of variations 12 through 14 and may further include at least one additional cooling system constructed and arranged to draw heat away from the at least one of a closed or open loop cooling system.

Variation 16 may include thermal energy conversion module as in any of variations 12 through 15 wherein the borehole is part of a pre-existing well or drilled hole.

Variation 17 may include thermal energy conversion module as in any of variations 12 through 16 wherein the at least one thermal energy conversion module includes a thermoelectric generator may include a hot side opposite a cool side.

Variation 18 may include a modular power plant system that may include a plurality of thermal energy conversion modules, each may include a thermoelectric generator may include an outer surface and an inner surface and defining a cavity therein, the thermal electric generator being constructed and arranged to convert temperature difference between the outer surface and the inner surface into electrical energy; a plurality of DC collectors in series constructed and arranged to collect electrical energy from the thermoelectric generator; and at least one DC to AC converter constructed and arranged to receive DC voltage from the DC collector; and at least one at least one of a closed or open loop cooling system disposed approximately within the cavity of each of the thermal energy conversion modules within the plurality of thermal energy conversion modules thermal electric converter.

Variation 19 may include a modular power plant system as in variation 18, wherein the at least one at least one of a closed or open loop cooling system includes a coolant delivery system and a coolant receiving system in operable communication with a surface infrastructure.

Variation 20 may include a modular power plant system as in variation 18 or 19 and may further include electrical subsystems in operable communication with the at least one DC to AC converter to operably communicate electrical energy from each of the plurality of thermal energy conversion modules to a surface infrastructure in operable communication with an electricity distribution system constructed and arranged to distribute electricity.

Many different embodiments have been disclosed herein, in connection with the above description and the drawings. It will be understood that it would be unduly repetitious and obfuscating to describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

An equivalent substitution of two or more elements can be made for anyone of the elements in the claims below or that a single element can be substituted for two or more elements in a claim. Although elements can be described above as acting in certain combinations, and even initially claimed as such, it is to be expressly understood that one or more elements from a claimed combination can, in some cases, be excised from the combination and that the claimed combination can be directed to a subcombination or variation of a subcombination.

It will be appreciated by persons skilled in the art that the present embodiment is not limited to what has been particularly shown and described hereinabove. A variety of modifications and variations are possible considering the above teachings without departing from the following claims.

What is claimed is:

1. A modular power plant system comprising:
an electricity distribution system;
a surface infrastructure in operable communication with the electricity distribution system;
at least one thermal energy conversion module disposed within a borehole within the earth crust and being in operable communication with the surface infrastructure, wherein the at least one thermal conversion module is constructed and arranged to convert geothermal heat to DC or AC voltage and communicate voltage to the surface infrastructure; and
at least one of a closed or open loop cooling system constructed and arranged to draw heat away from the at least one thermal energy conversion module and dissipate said heat via at least one of ambient cooling near surface level portions of the borehole or on the surface via a dedicated cooling system.

2. The modular power plant system as in claim 1, wherein the at least one thermal energy conversion module is a plurality of thermal energy conversion modules.

3. The modular power plant system as in claim 2, wherein the plurality of thermal energy conversion modules are disposed in in parallel within the borehole.

4. The modular power plant system as in claim 2, wherein the plurality of thermal energy conversion modules are disposed in series within the borehole.

5. The modular power plant system as in claim 2, wherein the plurality of thermal energy conversion modules are disposed partially in parallel and partially in series within the borehole.

6. The modular power plant system as in claim 1, further comprising at least one additional cooling system constructed and arranged to draw heat away from the at least one thermal energy conversion module.

7. The modular power plant system as in claim 1, wherein the borehole is part of a at least one of a pre-existing well, drilled hole, or structure with constant heat flow.

8. The modular power plant system as in claim 1, wherein the at least one thermal energy conversion module comprises a thermoelectric generator comprising a hot side opposite a cool side.

9. The modular power plant system as in claim 8, wherein the at least one of a closed or open loop cooling system is constructed and arranged to draw heat from the cool side of the thermoelectric generator and dissipate heat via at least one of ambient cooling near surface level portions of the borehole or a dedicated cooling system.

10. The modular power plant system as in claim 1, wherein the at least one thermal energy conversion module further comprises at least one DC collector in operable communication with at least DC to AC converter.

11. The modular power plant system as in claim 1, wherein the at least one of a closed or open loop cooling system comprises a coolant delivery system and a coolant receiving system in operable communication with surface infrastructure.

12. A thermal energy conversion module comprising:
a thermoelectric generator comprising an outer surface and an inner surface and defining a cavity therein, the thermal electric generator being constructed and arranged to convert temperature difference between the outer surface and the inner surface into electrical energy;
at least one of a closed or open loop cooling system disposed approximately withing the cavity of the thermal electric converter;
at least one DC collector constructed and arranged to collect electrical energy from the thermoelectric generator; and
at least one DC to AC converter constructed and arranged to receive DC voltage from the DC collector.

13. A thermal energy conversion module as in claim 12 wherein the at least one of a closed or open loop cooling system at least partially encapsulates the at least one DC collector and the at least one DC to AC converter.

14. A thermal energy conversion module as in claim 12, wherein the at least one of a closed or open loop cooling system comprises a coolant delivery system and a coolant receiving system in operable communication with surface infrastructure.

15. A thermal energy conversion module as in claim 12, further comprising at least one additional cooling system constructed and arranged to draw heat away from the at least one of a closed or open loop cooling system.

16. A thermal energy conversion module as in claim 12, wherein the borehole is part of a pre-existing well or drilled hole.

17. A thermal energy conversion module as in claim 12, wherein the at least one thermal energy conversion module comprises a thermoelectric generator comprising a hot side opposite a cool side.

18. A modular power plant system comprising:
a plurality of thermal energy conversion modules, each comprising
a thermoelectric generator comprising an outer surface and an inner surface and defining a cavity therein, the thermal electric generator being constructed and arranged to convert temperature difference between the outer surface and the inner surface into electrical energy;
a plurality of DC collectors in series constructed and arranged to collect electrical energy from the thermoelectric generator; and
at least one DC to AC converter constructed and arranged to receive DC voltage from the DC collector; and
at least one at least one of a closed or open loop cooling system disposed approximately within the cavity of each of the thermal energy conversion modules within the plurality of thermal energy conversion modules thermal electric converter.

19. The modular power plant system as in claim 18, wherein the at least one at least one of a closed or open loop cooling system comprises a coolant delivery system and a coolant receiving system in operable communication with a surface infrastructure.

20. The modular power plant system as in claim 18, further comprising electrical subsystems in operable communication with the at least one DC to AC converter to operably communicate electrical energy from each of the plurality of thermal energy conversion modules to a surface infrastructure in operable communication with an electricity distribution system constructed and arranged to distribute electricity.
